(19) United States
(12) Patent Application Publication
(10) Pub. No.: US 2024/0120354 A1
(43) Pub. Date: Apr. 11, 2024

(54) SEMICONDUCTOR PACKAGE

(71) Applicant: SAMSUNG ELECTRONICS CO, LTD., Suwon-si (KR)

(72) Inventor: Kyong Soon CHO, Suwon-si (KR)

(73) Assignee: SAMSUNG ELECTRONICS CO, LTD., Suwon-si (KR)

(21) Appl. No.: 18/371,258

(22) Filed: Sep. 21, 2023

(30) Foreign Application Priority Data
Oct. 7, 2022 (KR) 10-2022-0129065

(51) Int. Cl. H01L 27/146; H01L 23/00

(52) U.S. Cl. CPC H01L 27/14618; H01L 24/05; H01L 24/06; H01L 24/29; H01L 24/32; H01L 24/45; H01L 24/48; H01L 24/49; H01L 24/73; H01L 27/14621; H01L 27/14685; H01L 24/33; H01L 24/83; H01L 24/92; H01L 27/14627; H01L 27/1464; H01L 2224/05551; H01L 2224/05554; H01L 2224/05567; H01L 2224/05624; H01L 2224/0603; H01L 2224/06051; H01L 2224/06155; H01L 2224/06515; H01L 2224/29011; H01L 2224/29013; H01L 2224/29035; H01L 2224/2919; H01L 2224/2929; H01L 2224/32225; H01L 2224/33181; H01L 2224/45144; H01L 2224/48091; H01L 2224/48108; H01L 2224/48227; H01L 2224/49171; H01L 2224/73215; H01L 2224/73265; H01L 2224/83191; H01L 2224/83192; H01L 2224/83862; H01L 2224/83986; H01L 2224/92165; H01L 2224/92247; H01L 2924/0665

(57) ABSTRACT

A semiconductor package includes a package substrate, a semiconductor chip on the package substrate, a transparent substrate on the semiconductor chip, a dam structure between the semiconductor chip and the transparent substrate, a dummy pad on a lower side of the dam structure and to which no wiring is connected, a planarization film extending along an upper surface of the semiconductor chip and a passivation film on the planarization film, wherein the planarization film is spaced apart from the dam structure.

### CROSS-REFERENCE TO RELATED APPLICATION

This application claims priority to Korean Patent Application No. 10-2022-0129065 filed on Oct. 7, 2022, in the Korean Intellectual Property Office, the disclosure of which is incorporated by reference herein in its entirety.

### BACKGROUND

### 1. Field

The disclosure relates to a semiconductor package.

### 2. Description of Related Art

An image sensor is a semiconductor element that converts optical information into electrical signals. Such an image sensor may include a charge coupled device (CCD) image sensor and a complementary metal-oxide semiconductor (CMOS) image sensor.

The image sensor may be configured in the form of a package. The image sensor package may include a dam structure for fixing a transparent substrate to an image sensor chip. In addition, the image sensor chip may include a planarization film for stably forming a micro lens and a passivation film for protecting the micro lens.

### SUMMARY

One or more example embodiments of the disclosure provide a semiconductor package with improved product reliability.

In accordance with an aspect of an example embodiment, a semiconductor package includes a package substrate; a semiconductor chip on the package substrate; a transparent substrate on the semiconductor chip; a dam structure between the semiconductor chip and the transparent substrate; a dummy pad on a lower side of the dam structure and to which no wiring is connected; a planarization film extending along an upper surface of the semiconductor chip; and a passivation film on the planarization film, wherein the planarization film is spaced apart from the dam structure.

In accordance with an aspect of an example embodiment, a semiconductor package includes a package substrate; an image sensor chip on the package substrate, the image sensor chip including a plurality of micro lenses at a central portion of the image sensor chip; a plurality of chip pads on an upper surface of the image sensor chip; a dummy pad on the upper surface of the image sensor chip, wherein a distance from the dummy pad to the central portion is smaller than a distance from the plurality of chip pads to the central portion, wherein the dummy pad surrounds the central portion; a dam structure on the plurality of chip pads and the dummy pad, the dam structure surrounding the central portion; a transparent substrate on the image sensor chip and the dam structure; and a plurality of substrate pads on an upper surface of the package substrate and surrounding the image sensor chip, wherein the plurality of chip pads and the plurality of substrate pads are connected to each other by bonding wires, and wherein the dummy pad and the plurality of substrate pads are not connected to each other.

In accordance with an aspect of an example embodiment, a semiconductor package includes a package substrate including a plurality of substrate pads; an image sensor chip on the package substrate; a plurality of chip pads on an upper surface of the image sensor chip; a dummy pad on the upper surface of the image sensor chip, wherein a distance from the dummy pad to a central portion of the image sensor chip is smaller than a distance from the plurality of chip pads to the central portion; a dam structure on the plurality of chip pads and the dummy pad; and a transparent substrate on the image sensor chip and the dam structure, wherein the image sensor chip includes a plurality of micro lenses; a planarization film on a lower side of the plurality of micro lenses; and a passivation film covering the plurality of micro lenses, wherein the planarization film is spaced apart from the dam structure, wherein the passivation film covers a side surface of the planarization film and extends to a lower side of the dam structure, wherein the plurality of chip pads and the plurality of substrate pads are connected to each other by bonding wires, and wherein the dummy pad and the plurality of substrate pads are not connected to each other.

Aspects of the disclosure are not restricted to those set forth herein. The above and other aspects of the disclosure will become more apparent to one of ordinary skill in the art to which the disclosure pertains by referencing the detailed description of the disclosure given below.

### BRIEF DESCRIPTION OF THE DRAWINGS

The above and other aspects and features of the disclosure will become more apparent by describing in detail example embodiments thereof with reference to the attached drawings, in which:

FIG. 1 is a schematic layout view illustrating a semiconductor package according to example embodiments;

FIG. 2 is a schematic cross-sectional view taken along line A-A of FIG. 1;

FIG. 3 is an enlarged view of part R of FIG. 2;

FIG. 4 is an enlarged view of part P of FIG. 2;

FIGS. 5 to 7 are views for describing a semiconductor package according to example embodiments;

FIG. 8 is a view for describing a semiconductor package according to example embodiments;

FIG. 9 is a view for describing a semiconductor package according to example embodiments;

FIG. 10 is a view for describing a semiconductor package according to example embodiments;

FIG. 11 is a view for describing a semiconductor package according to example embodiments; and

FIGS. 12 to 22 are intermediate step views for describing a method of manufacturing a semiconductor package according to example embodiments.

### DETAILED DESCRIPTION

Hereinafter, example embodiments of the disclosure will be described with reference to the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

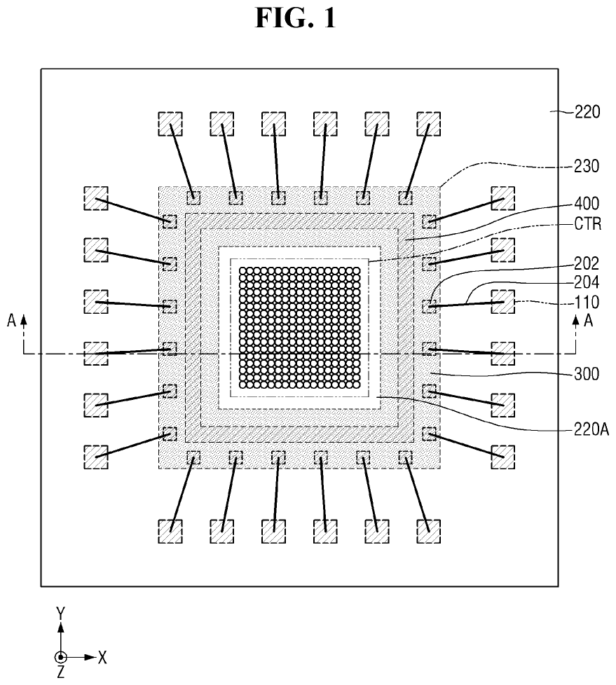

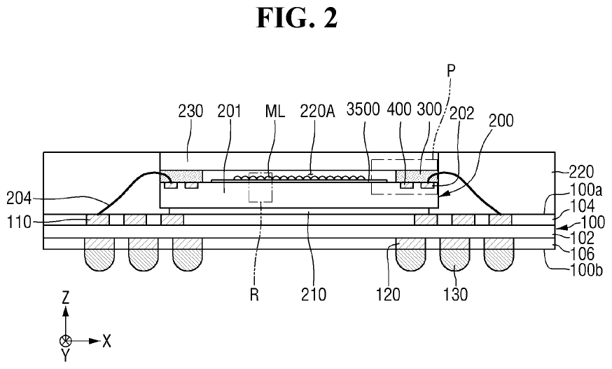

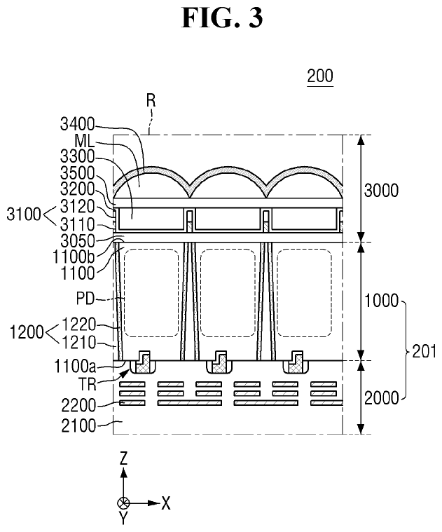

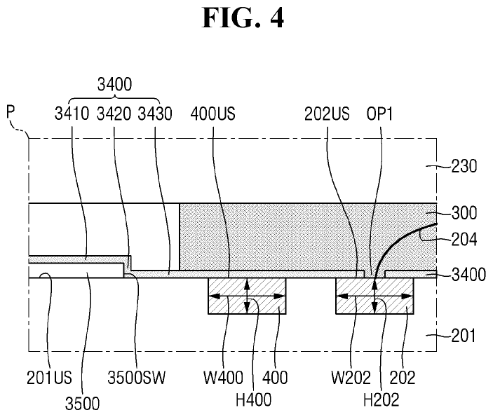

FIG. 1 is a schematic layout view illustrating a semiconductor package according to some example embodiments. FIG. 2 is a schematic cross-sectional view taken along line A-A of FIG. 1. FIG. 3 is an enlarged view of part R of FIG. 2. FIG. 4 is an enlarged view of part P of FIG. 2.

Referring to FIGS. 1 to 4, a semiconductor package according to some example embodiments includes a first package substrate 100, a first connection terminal 130, a first semiconductor chip 200, a transparent substrate 230, a mold layer 220, a dam structure 300, a dummy pad 400, and a planarization film 3500.

The first package substrate 100 may be a substrate for a semiconductor package. As an example, the first package substrate 100 may be a printed circuit board (PCB). Alternatively, the first package substrate 100 may be a ceramic substrate, or a substrate for a wafer level package (WLP) or a substrate for a package level package (PLP).

The first package substrate 100 may include a first surface 100a and a second surface 100b that are opposite to each other. In some embodiments, the first package substrate 100 may include a first wiring layer 102, a first substrate pad 110, and a second substrate pad 120.

The first substrate pad 110 may be disposed on an upper surface of the first wiring layer 102. The first substrate pad 110 may be exposed from an upper surface of the first package substrate 100. For example, the first substrate pad 110 may be exposed by a first passivation layer 104 covering the upper surface of the first wiring layer 102. The first passivation layer 104 may be a solder resist layer, but is not limited thereto.

The second substrate pad 120 may be disposed on a lower surface of the first wiring layer 102. The second substrate pad 120 may be exposed from a lower surface of the first package substrate 100. For example, the second substrate pad 120 may be exposed by a second passivation layer 106 covering the lower surface of the first wiring layer 102. The second passivation layer 106 may be a solder resist layer, but is not limited thereto.

The first wiring layer 102 may include insulating films made of a plastic material or a ceramic material, and conductive vias and conductive wirings disposed in the insulating films. The first substrate pad 110 and the second substrate pad 120 may be electrically connected to each other by the conductive vias and the conductive wirings of the first wiring layer 102.

The first wiring layer 102 may include, for example, at least one of a phenol resin, an epoxy resin, and a polyimide, but is not limited thereto. For example, the first wiring layer 102 may include at least one of flame retardant 4 (FR4), tetrafunctional epoxy, polyphenylene ether, epoxy/polyphenylene oxide, bismaleimide triazine (BT), thermount, cyanate ester, polyimide, and liquid crystal polymer.

Each of the first substrate pad 110 and the second substrate pad 120 may include at least one of copper (Cu), beryllium copper, nickel (Ni), and stainless steel, but is not limited thereto.

In some example embodiments, the first package substrate 100 may include a copper clad laminate (CCL). For example, the first package substrate 100 may have a structure in which a copper laminate is laminated on one side or both sides of a thermosetting prepreg (e.g., C-Stage prepreg). As an example, the first substrate pad 110 and the second substrate pad 120 may be portions exposed by the first passivation layer 104 and the second passivation layer 106 among circuit wirings formed by patterning after coating a copper laminate on a surface of the first wiring layer 102.

The first connection terminal 130 may be disposed on the second surface 100b of the first package substrate 100. The first connection terminal 130 may be electrically connected to the first package substrate 100. For example, the first connection terminal 130 may be attached to the second substrate pad 120 of the first package substrate 100. The first connection terminal 130 may be, for example, a solder ball, a bump, or the like. That is, the first package substrate 100 may be a ball grid array (BGA) substrate. The first connection terminal 130 may include a metal such as tin (Sn), but is not limited thereto. The first connection terminal 130 may electrically connect the semiconductor package according to some example embodiments to an external electronic device.

The first semiconductor chip 200 may be mounted on the first surface 100a of the first package substrate 100. For example, an attachment film 210 may be formed on the first surface 100a of the first package substrate 100. The attachment film 210 may include, for example, a liquid epoxy, an adhesive tape, or a conductive medium, but is not limited thereto.

The first semiconductor chip 200 may be attached onto the attachment film 210 and fixed on the first surface 100a of the first package substrate 100. The first semiconductor chip 200 may include a body portion 201. The body portion 201 of the first semiconductor chip 200 may be disposed on the attachment film 210.

The first semiconductor chip 200 may be electrically connected to the first package substrate 100. In some example embodiments, a bonding wire 204 connecting the first package substrate 100 to the first semiconductor chip 200 may be formed. As an example, the first semiconductor chip 200 may include a first chip pad 202 exposed from an upper surface of the first semiconductor chip 200. The first chip pad 202 may include a metal material. For example, the first chip pad 202 may include aluminum (Al). However, the disclosure is not limited thereto.

The bonding wire 204 may connect the first substrate pad 110 of the first package substrate 100 to the first chip pad 202 of the first semiconductor chip 200. The bonding wire 204 may include, for example, a metal such as gold (Au), but is not limited thereto.

The first semiconductor chip 200 may include a dummy pad 400. The dummy pad 400 may be exposed from the upper surface of the first semiconductor chip 200. That is, an upper surface 400US of the dummy pad 400 may be disposed on the same plane as an upper surface 201US of the body portion 201 of the first semiconductor chip 200.

The dummy pad 400 may be disposed inside the first chip pad 202. The dummy pad 400 may be disposed closer to a central portion CTR than the first chip pad 202. In other words, a distance from the dummy pad 400 to the central portion CTR may be smaller than a distance from the first chip pad 202 to the central portion CTR. The dummy pad 400 may surround the central portion CTR. The dummy pad 400 may have a quadrangular ring shape. The dummy pad 400 may be surrounded by the first chip pad 202. That is, the dummy pad 400 may be disposed inside a plurality of first chip pads 202.

The dummy pad 400 may include a metal material. For example, the dummy pad 400 may include aluminum (Al). However, embodiments of the disclosure are not limited thereto. The dummy pad 400 may include the same material as that of the first chip pad 202.

The bonding wire 204 may not be connected to the dummy pad 400. That is, none of the bonding wires 204 may connect the dummy pad 400 to the first substrate pad 110.

Although it is illustrated that the first semiconductor chip 200 is electrically connected to the first package substrate 100 by the bonding wire 204, this is only an example. For example, the first semiconductor chip 200 may also be electrically connected to the first package substrate 100 by a bonding tape or may also be electrically connected to the first package substrate 100 by a flip chip bonding method.

In some example embodiments, the first semiconductor chip 200 may be an image sensor chip. For example, as illustrated in FIG. 3, the first semiconductor chip 200 may include a photoelectric conversion portion 1000, a wiring structure portion 2000, and a light transmitting portion 3000. The body portion 201 of the first semiconductor chip 200 may include the photoelectric conversion portion 1000 and the wiring structure portion 2000.

The photoelectric conversion portion 1000 may include a semiconductor substrate 1100, a pixel separation pattern 1200, and a photoelectric conversion layer PD.

The semiconductor substrate 1100 may be, for example, bulk silicon or silicon-on-insulator (SOI). The semiconductor substrate 1100 may also be a silicon substrate or may include other materials, for example, silicon germanium, indium antimonide, a lead tellurium compound, indium arsenide, indium phosphide, gallium arsenide, or gallium antimonide. Alternatively, the semiconductor substrate 1100 may have an epitaxial layer formed on a base substrate.

The semiconductor substrate 1100 may include a front side 1100a and a back side 1100b that are opposite to each other. In some example embodiments, the back side 1100b of the semiconductor substrate 1100 may be a light receiving surface on which light is incident. That is, the first semiconductor chip 200 may be a backside illuminated (BSI) image sensor chip.

In some example embodiments, transistors TR may be disposed on the front side 1100a of the semiconductor substrate 1100. The transistors TR may include, for example, at least some of various transistors (e.g., a transfer transistor, a reset transistor, a source follower transistor, and a selection transistor) constituting a unit pixel of the image sensor.

The pixel separation pattern 1200 may define a plurality of unit pixels in the semiconductor substrate 1100. The unit pixels may be arranged two-dimensionally (e.g., in a matrix form) in plan view. For example, the pixel separation pattern 1200 may be formed in a grid shape in plan view to separate the unit pixels from each other. The pixel separation pattern 1200 may be formed, for example, by filling an insulating material in a deep trench formed by patterning the semiconductor substrate 1100.

In some example embodiments, the pixel separation pattern 1200 may include an insulating spacer film 1220 and a conductive filling pattern 1210. The insulating spacer film 1220 may conformally extend along a side surface of the trench in the semiconductor substrate 1100. The conductive filling pattern 1210 may be formed on the insulating spacer film 1220 to fill at least a portion of the trench in the semiconductor substrate 1100.

Each of the unit pixels may include a photoelectric conversion layer PD. The photoelectric conversion layers PD may be formed in the semiconductor substrate 1100. The photoelectric conversion layer PD may generate electric charges in proportion to an amount of light incident from the outside. The photoelectric conversion layer PD may be formed by doping impurities in the semiconductor substrate 1100. For example, the photoelectric conversion layer PD may be formed by ion-implanting n-type impurities into a p-type semiconductor substrate 1100.

The wiring structure portion 2000 may be disposed on the front side 1100a of the semiconductor substrate 1100. The wiring structure portion 2000 may cover the transistors TR. The wiring structure portion 2000 may include readout circuits and sampling circuits electrically connected to the photoelectric conversion layer PD. For example, the wiring structure portion 2000 may include an inter-wiring insulating film 2100 covering the front side 1100a of the semiconductor substrate 1100 and wirings 2200 in the inter-wiring insulating film 2100.

The light transmitting portion 3000 may be disposed on the back side 1100b of the semiconductor substrate 1100. The light transmitting portion 3000 may include a plurality of micro lenses ML. The micro lenses ML may be arranged to correspond to the unit pixels, respectively. For example, the micro lenses ML may be arranged two-dimensionally (e.g., in a matrix form) in plan view. The micro lenses ML may be disposed at the central portion CTR. The micro lenses ML may be disposed on the planarization film 3500.

The micro lenses ML may have a convex shape and may have a predetermined radius of curvature. Accordingly, the micro lenses ML may condense the light incident on the photoelectric conversion layer PD. The micro lenses ML may include, for example, a light transmitting resin, but are not limited thereto.

In some example embodiments, the light transmitting portion 3000 may further include a surface insulating film 3050 and a color filter 3300. The surface insulating film 3050 may be laminated on the back side 1100b of the semiconductor substrate 1100. The color filter 3300 may be disposed on the surface insulating film 3050. The color filter 3300 may be arranged to correspond to each of the unit pixels UP.

In some example embodiments, a grid pattern 3100 may be formed between the color filters 3300. The grid pattern 3100 may be formed on the surface insulating film 3050. In some example embodiments, the grid pattern 3100 may include a metal pattern 3110 and a low refractive index pattern 3120. The metal pattern 3110 and the low refractive index pattern 3120 may be sequentially laminated on the surface insulating film 3050, for example.

In some example embodiments, a first liner 3200 may be further formed on the surface insulating film 3050 and the grid pattern 3100. The first liner 3200 may include, for example, aluminum oxide, but is not limited thereto.

In some example embodiments, a passivation film 3400 may be further formed on the micro lens ML. The passivation film 3400 may extend along a surface of each micro lens ML. The passivation film 3400 may include, for example, an inorganic oxide film (e.g., silicon oxide, titanium oxide, zirconium oxide, hafnium oxide, and combinations thereof), but is not limited thereto.

The planarization film 3500 may be disposed on a lower side of the micro lens ML. The planarization film 3500 may be formed to be flat on the grid pattern 3100. The planarization film 3500 may include, for example, at least one of a silicon oxide film-group material, a silicon nitride film-group material, a resin, or a combination thereof. Although the planarization film 3500 is illustrated as a single film, it is only for convenience of explanation and the disclosure is not limited thereto.

The planarization film 3500 may extend on the lower side of the micro lens ML. The planarization film 3500 may be spaced apart from the dam structure 300 (see, e.g., FIG. 4). That is, the planarization film 3500 may not extend to the dam structure 300. The planarization film 3500 may not overlap the dam structure 300. The planarization film 3500 may not overlap the dummy pad 400 disposed on a lower side of the dam structure 300.

The passivation film 3400 may be formed with a constant thickness along the surface of the micro lens ML. The passivation film 3400 may be an inorganic oxide film. For example, a silicon oxide film (SiO2), a titanium oxide film (TiO2), a zirconium oxide film (ZrO2), a hafnium oxide film (HfO2), a laminated film thereof, or a combination film may be used. In particular, as the passivation film 3400, low temperature oxide (LTO), which is a kind of silicon oxide film, may be used. The reason for using LTO in this way is that, LTO is manufactured at a low temperature (about 100° C. to 200° C.) and thus causes less damage to the lower films. In addition, since LTO is amorphous, a surface thereof is smooth, so that reflection/refraction/scattering of incident light may be minimized.

The passivation film 3400 may extend from the central portion CTR at which the micro lenses ML are disposed to the lower side of the dam structure 300. The passivation film 3400 may cover the planarization film 3500. The passivation film 3400 may extend on the planarization film 3500. The passivation film 3400 may include a first extension portion 3410, a vertical portion 3420, and a second extension portion 3430.

The first extension portion 3410 may extend on the planarization film 3500. The first extension portion 3410 may vertically overlap the planarization film 3500. The second extension portion 3430 may extend from a side of the planarization film 3500. The second extension portion 3430 may not vertically overlap the planarization film 3500. The vertical portion 3420 may cover a side surface 3500SW of the planarization film 3500. The vertical portion 3420 may extend along the side surface of the planarization film 3500. The vertical portion 3420 may be bent from the first extension portion 3410. The vertical portion 3420 may be bent from the second extension portion 3430. The vertical portion 3420 may connect the first extension portion 3410 and the second extension portion 3430 to each other.

The passivation film 3400 may be disposed on the lower side of the dam structure 300. A portion of the passivation film 3400 may be covered by the dam structure 300. The passivation film 3400 may extend on the dummy pad 400 and the first chip pad 202.

The transparent substrate 230 may be disposed on the upper surface of the first semiconductor chip 200. The transparent substrate 230 may face the first semiconductor chip 200. The transparent substrate 230 may face the micro lenses ML of the first semiconductor chip 200. The light provided to the semiconductor package may pass through the transparent substrate 230 and reach the first semiconductor chip 200. The transparent substrate 230 may be, for example, a glass substrate or a plastic substrate, but is not limited thereto.

The transparent substrate 230 may be disposed on the dam structure 300. The transparent substrate 230 may be attached onto the first semiconductor chip 200 through the dam structure 300.

An upper surface of the transparent substrate 230 may be flat. The upper surface of the transparent substrate 230 may not include any step difference. The transparent substrate 230 may receive light through the front side thereof. The upper surface of the transparent substrate 230 may receive light through an entire area thereof.

The dam structure 300 may be disposed between the first semiconductor chip 200 and the transparent substrate 230. The dam structure 300 may fix the transparent substrate 230 on the upper surface of the first semiconductor chip 200. The dam structure 300 may include, for example, an epoxy resin composition containing a filler, but is not limited thereto.

The dam structure 300 may block light. The dam structure 300 may have a lower light transmittance than that of the transparent substrate 230. The dam structure 300 may have a higher light absorption than that of the transparent substrate 230. The dam structure 300 may be opaque.

In some example embodiments, the dam structure 300 may define a gap 220A between the first semiconductor chip 200 and the transparent substrate 230. For example, the dam structure 300 may extend along an edge of the first semiconductor chip 200 in plan view to form a closed ring as shown, e.g., in FIG. 1. Accordingly, the transparent substrate 230 may be spaced apart from the first semiconductor chip 200 by the gap 220A. The plurality of micro lenses ML of the first semiconductor chip 200 may be disposed in the gap 220A.

The dam structure 300 may surround the plurality of micro lenses ML in plan view. The dam structure 300 may not overlap the plurality of micro lenses ML in plan view. The dam structure 300 may be disposed on a lower side of the transparent substrate 230 that does not overlap the plurality of micro lenses ML.

The dam structure 300 may be disposed on the dummy pad 400 and the first chip pad 202. The dam structure 300 may cover the dummy pad 400 and the first chip pad 202. The dam structure 300 may be disposed on the passivation film 3400.

The dummy pad 400 may be disposed closer to the planarization film 3500 than the first chip pad 202. In other words, a distance from the dummy pad 400 to the planarization film 3500 may be smaller than a distance from the first chip pad 202 to the planarization film 3500. The dummy pad 400 may be completely covered by the passivation film 3400. That is, the upper surface 400US of the dummy pad 400 may not be exposed from the passivation film 3400.

The first chip pad 202 may not be completely covered by the passivation film 3400. A first opening OP1 may be disposed on the first chip pad 202. The first opening OP1 may be formed in the passivation film 3400.

The first opening OP1 may expose an upper surface 202US of the first chip pad 202 between the passivation films 3400. That is, at least a portion of the upper surface 202US of the first chip pad 202 may be exposed from the passivation film 3400 through the first opening OP1. The first chip pad 202 may be connected to the bonding wire 204 through the first opening OP1. The first chip pad 202 may be in contact with the dam structure 300 through the first opening OP1.

The upper surface 400US of the dummy pad 400 and the upper surface 202US of the first chip pad 202 may be disposed on the same plane. In addition, the upper surface 400US of the dummy pad 400 and the upper surface 202US of the first chip pad 202 may be disposed on the same plane as the upper surface 201US of the body portion 201 of the first semiconductor chip 200. That is, based on the upper surface 201US of the body portion 201 of the first semiconductor chip 200, the dummy pad 400 and the first chip pad 202 may be inserted into the body portion 201 of the first semiconductor chip 200.

A size of the dummy pad 400 and a size of the first chip pad 202 may be the same. For example, a height H400 of the dummy pad 400 and a height H₂O₂ of the first chip pad 202 may be the same. In addition, a width W400 of the dummy pad 400 and a width W202 of the first chip pad 202 may be the same.

The mold layer 220 may be disposed on the first package substrate 100. The mold layer 220 may surround the first semiconductor chip 200, the transparent substrate 230, and the dam structure 300. The mold layer 220 may be disposed on side surfaces of the first semiconductor chip 200, the transparent substrate 230, and the dam structure 300. The mold layer 220 may cover the bonding wire 204.

The mold layer 220 may include an insulating material. For example, the mold layer 220 may include a thermosetting resin such as an epoxy resin, a thermoplastic resin such as polyimide, a resin in which the thermosetting resin and the thermoplastic resin are mixed with inorganic filler or are impregnated together with inorganic filler in a core material such as a glass fiber (or a glass cloth or a glass fabric) (e.g., prepreg, Ajinomoto Build up Film (ABF), FR-4, or Bismaleimide Triazine (BT)), or the like. Alternatively, the mold layer 220 may also include a photoimageable dielectric (PID).

An upper surface of the mold layer 220 may be disposed on the same plane as the upper surface of the transparent substrate 230. A side surface of the mold layer 220 may be disposed on the same plane as a side surface of the first package substrate 100.

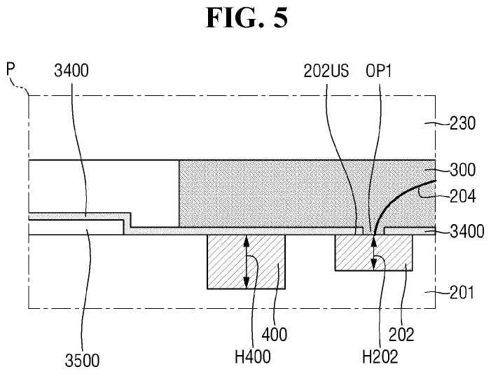

FIGS. 5 to 7 are views for describing a semiconductor package according to some example embodiments. For convenience of explanation, points different from those described with reference to FIGS. 1 to 4 will be mainly described.

Referring to FIG. 5, the sizes of the dummy pad 400 and the first chip pad 202 may be different. For example, the height H400 of the dummy pad 400 may be different from the height H202 of the first chip pad 202. Specifically, the height H400 of the dummy pad 400 may be greater than the height H202 of the first chip pad 202.

Although it is illustrated in FIG. 5 that the height H400 of the dummy pad 400 is greater than the height H202 of the first chip pad 202, example embodiments are not limited thereto. For example, the height H400 of the dummy pad 400 may be smaller than the height H202 of the first chip pad 202.

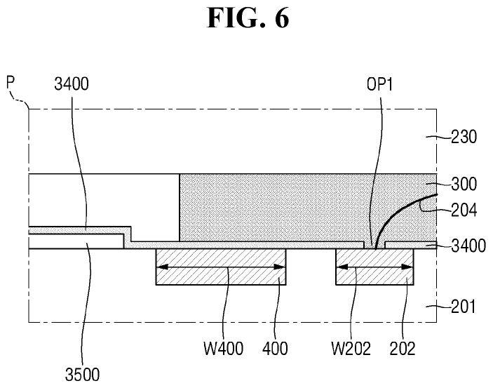

Referring to FIG. 6, the width W400 of the dummy pad 400 may be different from the width W202 of the first chip pad 202. For example, the width W400 of the dummy pad 400 may be greater than the width W202 of the first chip pad 202. The dummy pad 400 may not completely overlap the dam structure 300. The dummy pad 400 may include a portion that does not vertically overlap the dam structure 300. A portion of the dummy pad 400 may not overlap the dam structure 300 and may protrude toward the planarization film 3500 in a horizontal direction with respect to an inner surface of the dam structure 300.

Although it is illustrated in FIG. 6 that the width W400 of the dummy pad 400 is greater than the width W202 of the first chip pad 202, example embodiments are not limited thereto. For example, the width W400 of the dummy pad 400 may be smaller than the width W202 of the first chip pad 202.

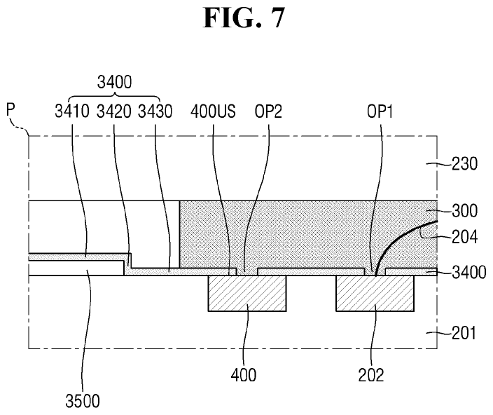

Referring to FIG. 7, the dummy pad 400 and the first chip pad 202 may not be completely covered by the passivation film 3400. For example, a second opening OP2 may be disposed on the dummy pad 400.

The second opening OP2 may be formed in the passivation film 3400. The second opening OP2 may expose the upper surface 400US of the dummy pad 400 between the passivation films 3400 (e.g., between adjacent portions of the passivation film 3400). That is, at least a portion of the upper surface 400US of the dummy pad 400 may be exposed from the passivation film 3400 through the second opening OP2. A portion of the upper surface 400US of the dummy pad 400 may be in contact with the dam structure 300. A portion of the upper surface 202US of the first chip pad 202 may be in contact with the dam structure 300.

Even though the upper surface 400US of the dummy pad 400 is exposed from the passivation film 3400 through the second opening OP2, the dummy pad 400 may not be connected to the bonding wire 204.

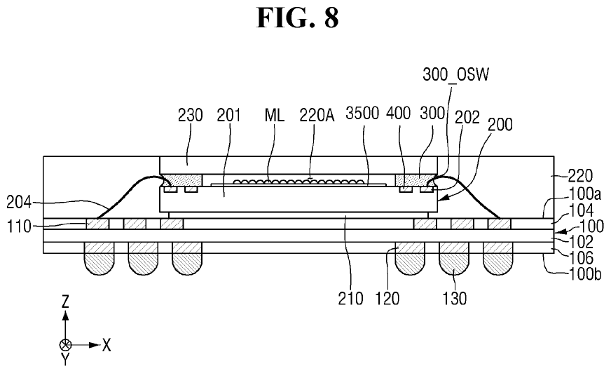

FIG. 8 is a view for describing a semiconductor package according to example embodiments. For convenience of explanation, points different from those described with reference to FIGS. 1 to 4 will be mainly described.

Referring to FIGS. 1 and 8, the dam structure 300 may have a concave outer sidewall 300_OSW. The outer sidewall 300_OSW of the dam structure 300 may be inwardly recessed. The outer sidewall 300_OSW of the dam structure 300 may be concavely bent toward the central portion CTR at which the micro lenses ML are disposed.

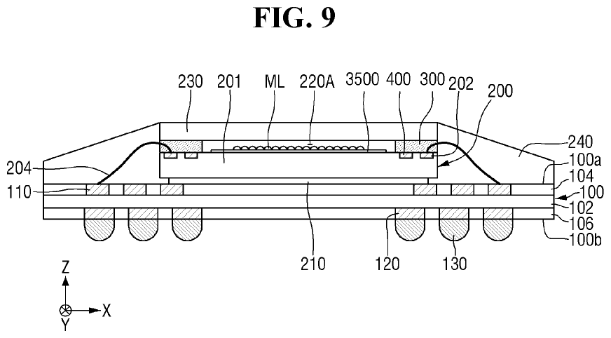

FIG. 9 is a view for describing a semiconductor package according to example embodiments. For convenience of explanation, points different from those described with reference to FIGS. 1 to 4 will be mainly described.

Referring to FIG. 9, the semiconductor package according to example embodiments may include an encapsulation film 240. The encapsulation film 240 may cover a sidewall of the first semiconductor chip 200, a sidewall of the dam structure 300, and a sidewall of the transparent substrate 230. An upper surface of the encapsulation film 240 may not be disposed on the same plane as that of the upper surface of the transparent substrate 230. The upper surface of the encapsulation film 240 may have a shape inclined with respect to the upper surface of the transparent substrate 230.

For example, the encapsulation film 240 may include an epoxy-group molding resin or a polyimide-group molding resin. The encapsulation film 240 may include an epoxy molding compound (EMC).

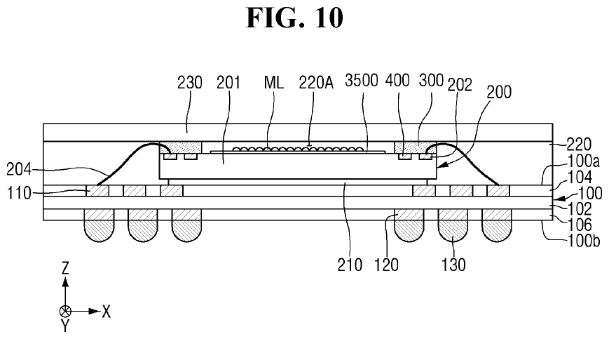

FIG. 10 is a view for describing a semiconductor package according to example embodiments. For convenience of explanation, points different from those described with reference to FIGS. 1 to 4 will be mainly described.

Referring to FIG. 10, in the semiconductor package according to example embodiments, the transparent substrate 230 may cover the upper surface of the mold layer 220. For example, the transparent substrate 230 may extend along the upper surface of the dam structure 300 and the upper surface of the mold layer 220. A lower surface of the transparent substrate 230 may cover the upper surface of the mold layer 220. The lower surface of the transparent substrate 230 may further extend outward compared to the dam structure 300.

The side surface of the transparent substrate 230 may be disposed on the same plane as the side surface of the first package substrate 100. The mold layer 220 may not cover the side surface of the transparent substrate 230.

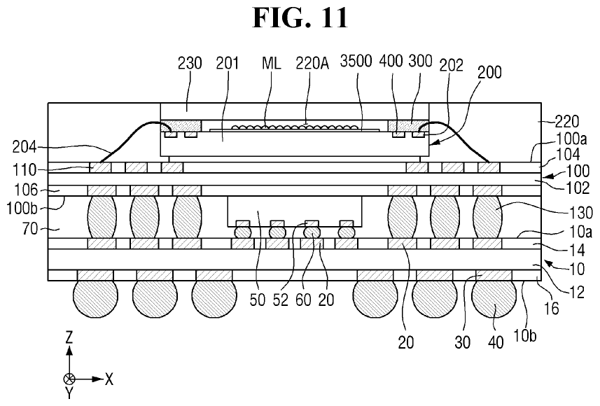

FIG. 11 is a view for describing a semiconductor package according to example embodiments. For convenience of explanation, points different from those described with reference to FIGS. 1 to 4 will be mainly described.

Referring to FIG. 11, the semiconductor package according to example embodiments may further include a second package substrate 10, a second connection terminal 40, a second semiconductor chip 50, and a third molding film 70.

The second package substrate 10 may be a substrate for a semiconductor package. As an example, the second package substrate 10 may be a printed circuit board (PCB). Alternatively, the second package substrate 10 may be a ceramic substrate, or a substrate for a wafer level package (WLP) or a substrate for a package level package (PLP).

The second package substrate 10 may include a third surface 10a and a fourth surface 10b that are opposite to each other. In example embodiments, the third surface 10a of the second package substrate 10 may face the second surface 100b of the first package substrate 100. In example embodiments, the second package substrate 10 may include a second wiring layer 12, a third substrate pad 20, and a fourth substrate pad 30.

The third substrate pad 20 may be disposed on an upper surface of the second wiring layer 12. The third substrate pad 20 may be exposed from an upper surface of the second package substrate 10. For example, the third substrate pad 20 may be exposed by a third passivation layer 14 covering the upper surface of the second wiring layer 12. The third passivation layer 14 may be a solder resist layer, but is not limited thereto.

The fourth substrate pad 30 may be disposed on a lower surface of the second wiring layer 12. The fourth substrate pad 30 may be exposed from a lower surface of the second package substrate 10. For example, the fourth substrate pad 30 may be exposed by a fourth passivation layer 16 covering the lower surface of the second wiring layer 12. The fourth passivation layer 16 may be a solder resist layer, but is not limited thereto.

The second wiring layer 12 may include insulating films made of a plastic material or a ceramic material, and conductive vias and conductive wirings disposed in the insulating films. The third substrate pad 20 and the fourth substrate pad 30 may be electrically connected to each other by the conductive vias and the conductive wirings of the second wiring layer 12.

The second connection terminal 40 may be disposed on the fourth surface 10b of the second package substrate 10. The second connection terminal 40 may be electrically connected to the second package substrate 10. For example, the second connection terminal 40 may be attached to the fourth substrate pad 30 of the second package substrate 10. The second connection terminal 40 may be, for example, a solder ball, a bump, or the like. The second connection terminal 40 may electrically connect the semiconductor package according to example embodiments to an external electronic device.

In example embodiments, the first package substrate 100 and the second package substrate 10 may be electrically connected to each other. For example, the first connection terminal 130 may connect the third substrate pad 20 of the second package substrate 10 to the second substrate pad 120 of the first package substrate 100.

The second semiconductor chip 50 may be mounted on the third surface 10a of the second package substrate 10. The second semiconductor chip 50 may be electrically connected to the second package substrate 10. In example embodiments, a third connection terminal 60 connecting the second package substrate 10 to the second semiconductor chip 50 may be formed. As an example, the second semiconductor chip 50 may include a second chip pad 52 exposed from a lower surface of the second semiconductor chip 50. The third connection terminal 60 may connect the third substrate pad 20 of the second package substrate 10 to the second chip pad 52 of the second semiconductor chip 50. That is, the second semiconductor chip 50 may be mounted on the second package substrate 10 by a flip chip bonding method. The third connection terminal 60 may be, for example, a micro bump, but is not limited thereto.

Although it is illustrated that the second semiconductor chip 50 is electrically connected to the second package substrate 10 by the flip chip bonding method, this is only an example. For example, the second semiconductor chip 50 may also be electrically connected to the second package substrate 10 by a bonding wire or a bonding tape.

In example embodiments, the second semiconductor chip 50 may include at least one of a memory semiconductor chip, a digital signal processing integrated circuit, an application specific integrated circuit (ASIC), and a driver, but is not limited thereto.

The third molding film 70 may be formed on the third surface 10a of the second package substrate 10. The third molding film 70 may fill a space between the first package substrate 100 and the second package substrate 10. For example, the third molding film 70 may surround a side surface of the second semiconductor chip 50. The first connection terminal 130 may penetrate through the third molding film 70 to connect the first package substrate 100 to the second package substrate 10. The third connection terminal 60 may penetrate through the third molding film 70 to connect the second package substrate 10 to the second semiconductor chip 50. The third molding film 70 may include, for example, an insulating polymer material such as an epoxy molding compound (EMC), but is not limited thereto.

The planarization film 3500 of the first semiconductor chip 200 may be spaced apart from the dam structure 300. The dummy pad 400 and the first chip pad 202 may be disposed on the lower side of the dam structure 300. The dummy pad 400 may be disposed closer to the planarization film 3500 than the first chip pad 202. In other words, a distance from the dummy pad 400 to the planarization film 3500 may be smaller than a distance from the first chip pad 202 to the planarization film 3500.

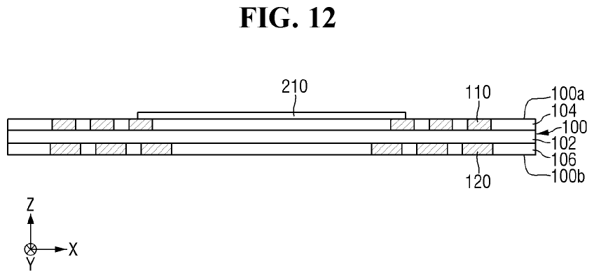

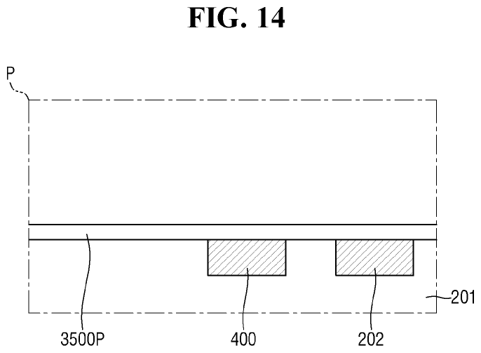

FIGS. 12 to 22 are intermediate step views for describing a method of manufacturing a semiconductor package according to example embodiments. For convenience of explanation, points different from those described with reference to FIGS. 1 to 4 will be mainly described.

Referring to FIG. 12, an attachment film 210 is formed on a first package substrate 100.

The first package substrate 100 may be a substrate for a semiconductor package. As an example, the first package substrate 100 may be a printed circuit board (PCB). The first package substrate 100 may include a first surface 100a and a second surface 100b that are opposite to each other. In example embodiments, the first package substrate 100 may include a first wiring layer 102, a first substrate pad 110, and a second substrate pad 120.

The attachment film 210 may be formed on the first surface 100a of the first package substrate 100. The attachment film 210 may include, for example, a liquid epoxy, an adhesive tape, or a conductive medium, but is not limited thereto.

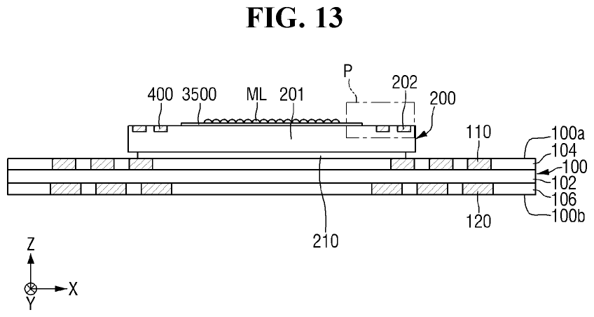

Referring to FIG. 13, a first semiconductor chip 200 is attached onto the attachment film 210.

The first semiconductor chip 200 may be attached onto the attachment film 210 and fixed on the first surface 100a of the first package substrate 100.

In example embodiments, the first semiconductor chip 200 may be an image sensor chip. For example, the first semiconductor chip 200 may include a plurality of micro lenses ML.

A dummy pad 400 and a first chip pad 202 may be formed on an upper surface of the first semiconductor chip 200. A planarization film 3500 and a plurality of micro lenses ML may be formed on a body portion 201 of the first semiconductor chip 200.

Specifically, the dummy pad 400 and the first chip pad 202 may be formed in the body portion 201 of the first semiconductor chip 200. Each of the upper surface of the dummy pad 400 and the upper surface of the first chip pad 202 may be disposed on the same plane as the upper surface of the body portion 201 of the first semiconductor chip 200. That is, the dummy pad 400 and the first chip pad 202 may be inserted into the body portion 201 to be exposed by the upper surface of the first body portion 201.

A pre-planarization film 3500P may be formed on the first body portion 201, the dummy pad 400, and the first chip pad 202. The pre-planarization film 3500P may cover the first body portion 201, the dummy pad 400, and the first chip pad 202.

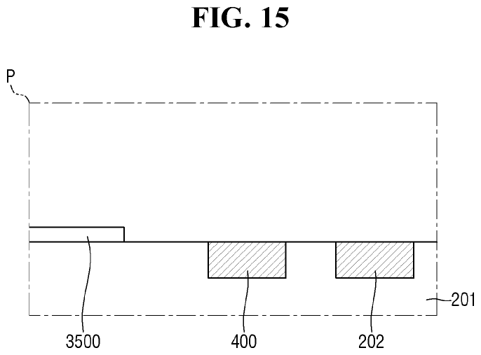

Next, referring to FIG. 15, a planarization film 3500 may be formed.

A portion of the pre-planarization film 3500P may be removed. The dummy pad 400 and the first chip pad 202 may be exposed without being covered by the planarization film 3500. The dummy pad 400 may prevent the pre-planarization film 3500P from being excessively removed. That is, the dummy pad 400 may be used as an etch stop film.

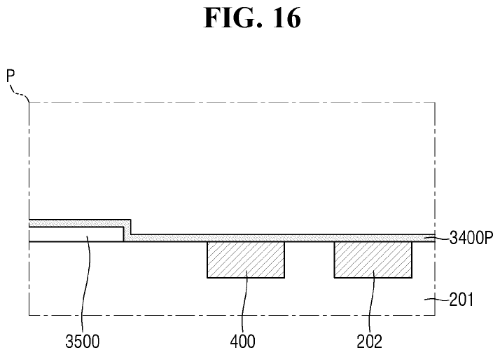

Next, referring to FIG. 16, a pre-passivation film 3400P may be formed.

The pre-passivation film 3400P may be formed on the planarization film 3500. The pre-passivation film 3400P may extend along the planarization film 3500, the body portion 201 of the first semiconductor chip 200, the upper surface of the dummy pad 400, and the upper surface of the first chip pad 202.

The pre-passivation film 3400P may surround a side surface of the planarization film 3500. That is, the pre-passivation film 3400P may extend along a step difference formed by the planarization film 3500.

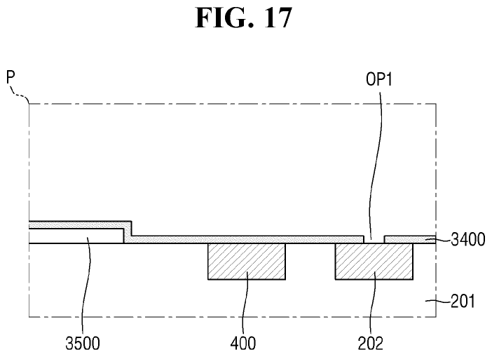

Referring to FIG. 17, a first opening OP1 and a passivation film 3400 are formed.

The first opening OP1 may be formed by removing a portion of the pre-passivation film 3400P. A portion of the upper surface of the first chip pad 202 may be exposed through the first opening OP1.

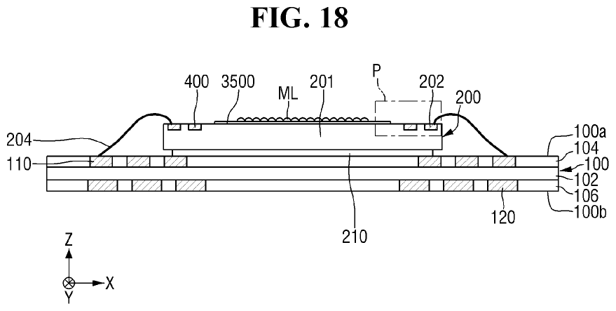

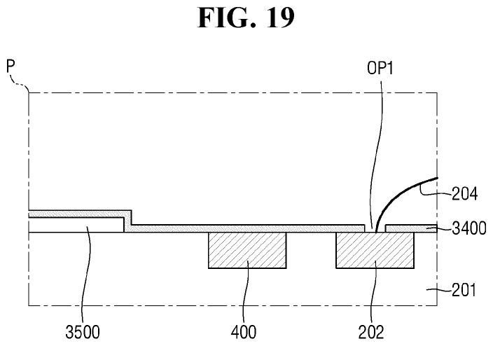

Referring to FIGS. 18 and 19, a bonding wire 204 connecting the first package substrate 100 to the first semiconductor chip 200 may be formed.

The bonding wire 204 may connect the first substrate pad 110 of the first package substrate 100 to the first chip pad 202 of the first semiconductor chip 200. The bonding wire 204 may include, for example, a metal such as gold (Au), but is not limited thereto.

The bonding wire 204 may be connected to the first chip pad 202 exposed through the first opening OP1 (see, e.g., FIG. 19). Therefore, the first chip pad 202 may be electrically connected to the first substrate pad 110.

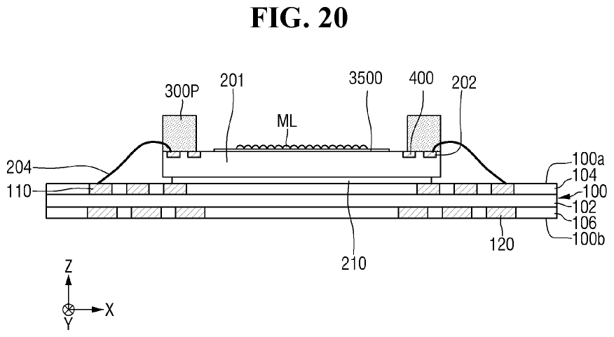

Referring to FIG. 20, a pre-dam structure 300P may be formed on the first semiconductor chip 200.

In example embodiments, the pre-dam structure 300P may extend along an edge of the first semiconductor chip 200 in plan view to form a closed ring. That is, the pre-dam structure 300P may be formed on the upper surface of the first semiconductor chip 200. In example embodiments, the pre-dam structure 300P may surround the plurality of micro lenses ML in plan view.

The pre-dam structure 300P may include, for example, an epoxy resin composition containing a filler, but is not limited thereto.

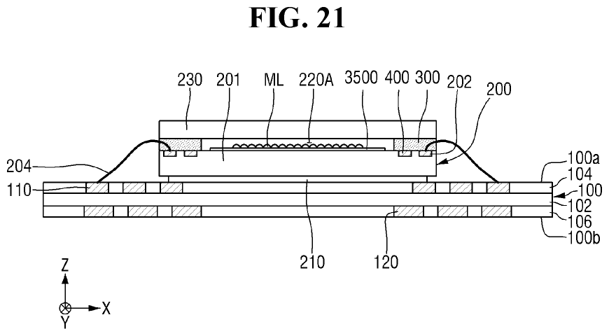

Referring to FIG. 21, a transparent substrate 230 may be attached onto the dam structure 300.

Specifically, the transparent substrate 230 may be disposed on the pre-dam structure 300P, and the pre-dam structure 300P may be cured. For example, the pre-dam structure 300P may be cured using heat or light. Therefore, the dam structure 300 may be formed. The transparent substrate 230 may be fixed on the first semiconductor chip 200 through the dam structure 300.

Accordingly, a gap 220A may be formed between the first semiconductor chip 200 and the transparent substrate 230. In example embodiments, the transparent substrate 230 may face the micro lenses ML of the first semiconductor chip 200. That is, the plurality of micro lenses ML of the first semiconductor chip 200 may be disposed in the gap 220A.

The transparent substrate 230 may be, for example, a glass substrate or a plastic substrate, but is not limited thereto. The transparent substrate 230 may face the first semiconductor chip 200.

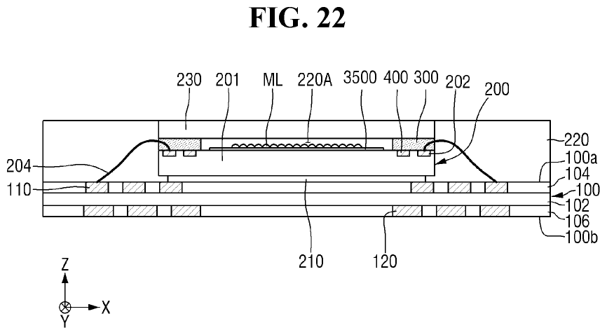

Referring to FIG. 22, a mold layer 220 is formed on the first surface 100a of the first package substrate 100.

The mold layer 220 may surround a side surface of the first semiconductor chip 200. The mold layer 220 may surround sidewalls of the first semiconductor chip 200, the transparent substrate 230, and the dam structure 300. The mold layer 220 may extend along an edge of the first package substrate 100 in plan view to form a closed ring. For example, the mold layer 220 may include an epoxy resin composition.

Next, referring to FIG. 2, a first connection terminal 130 may be formed on the second surface 100b of the first package substrate 100.

The first connection terminal 130 may be electrically connected to the first package substrate 100. For example, the first connection terminal 130 may be attached to the second substrate pad 120 of the first package substrate 100. The first connection terminal 130 may be, for example, a solder ball, a bump, or the like. The first connection terminal 130 may include a metal such as tin (Sn), but is not limited thereto.

In concluding the detailed description, those skilled in the art will appreciate that many variations and modifications may be made to the example embodiments without substantially departing from the principles of the disclosure. Therefore, the disclosed example embodiments of the disclosure are used in a generic and descriptive sense only and not for purposes of limitation.

What is claimed is:

1. A semiconductor package comprising:
a package substrate;
a semiconductor chip on the package substrate;
a transparent substrate on the semiconductor chip;
a dam structure between the semiconductor chip and the transparent substrate;
a dummy pad on a lower side of the dam structure and to which no wiring is connected;
a planarization film extending along an upper surface of the semiconductor chip; and
a passivation film on the planarization film and spaced apart from the dam structure.

2. The semiconductor package of claim 1, wherein the passivation film surrounds a side surface of the planarization film.

3. The semiconductor package of claim 1, further comprising a chip pad outside the dummy pad and on the lower side of the dam structure,
wherein the package substrate comprises a substrate pad,
wherein the substrate pad and the chip pad are connected to each other by a wire, and
wherein the dummy pad is not connected to the substrate pad.

4. The semiconductor package of claim 3, wherein the chip pad is exposed from the passivation film, and
wherein the chip pad is in contact with the dam structure.

5. The semiconductor package of claim 1, wherein the semiconductor chip comprises an image sensor.

6. The semiconductor package of claim 1, wherein the semiconductor chip comprises an image sensor chip comprising a color filter and a micro lens,
wherein the planarization film is on a lower side of the micro lens on the color filter, and
wherein the passivation film is on the micro lens.

7. The semiconductor package of claim 1, further comprising a mold layer on the package substrate, the mold layer covering side surfaces of each of the semiconductor chip, the dam structure, and the transparent substrate.

8. The semiconductor package of claim 1, wherein the dummy pad completely overlaps the dam structure.

9. The semiconductor package of claim 1, wherein a portion of the dummy pad does not overlap the dam structure.

10. The semiconductor package of claim 1, wherein the passivation film covers an entire upper surface of the dummy pad.

11. A semiconductor package comprising:
a package substrate;
an image sensor chip on the package substrate, the image sensor chip comprising a plurality of micro lenses at a central portion of the image sensor chip;
a plurality of chip pads on an upper surface of the image sensor chip;
a dummy pad on the upper surface of the image sensor chip, wherein a distance from the dummy pad to the central portion is smaller than a distance from the plurality of chip pads to the central portion, wherein the dummy pad surrounds the central portion;
a dam structure on the plurality of chip pads and the dummy pad, the dam structure surrounding the central portion;
a transparent substrate on the image sensor chip and the dam structure; and
a plurality of substrate pads on an upper surface of the package substrate and surrounding the image sensor chip,
wherein the plurality of chip pads and the plurality of substrate pads are connected to each other by bonding wires, and
wherein the dummy pad and the plurality of substrate pads are not connected to each other.

12. The semiconductor package of claim 11, wherein an upper surface of the dummy pad, upper surfaces of the plurality of chip pads, and the upper surface of the image sensor chip are on a same plane.

13. The semiconductor package of claim 11, wherein the image sensor chip further comprises:
a planarization film on a lower side of the plurality of micro lenses, and
a passivation film on the plurality of micro lenses, and
wherein the planarization film does not overlap the dam structure.

14. The semiconductor package of claim 13, wherein the passivation film comprises:
a first extension portion covering the planarization film,
a second extension portion extending from a side portion of the planarization film to a lower side of the dam structure, and
a vertical portion connecting the first extension portion to the second extension portion, wherein the vertical portion is spaced apart from the dam structure.

15. The semiconductor package of claim 14, wherein the second extension portion exposes a portion of upper surfaces of the plurality of chip pads to which the bonding wires are connected.

16. The semiconductor package of claim 11, wherein the dummy pad has a quadrangular ring shape exposing the central portion.

17. The semiconductor package of claim 11, wherein the plurality of chip pads and the dummy pad comprise a same material.

18. The semiconductor package of claim 11, wherein a width of the dummy pad is greater than a width of the plurality of chip pads.

19. The semiconductor package of claim 11, wherein the dam structure covers an entire upper surface of the dummy pad.

20. A semiconductor package comprising:
a package substrate comprising a plurality of substrate pads;
an image sensor chip on the package substrate;
a plurality of chip pads on an upper surface of the image sensor chip;
a dummy pad on the upper surface of the image sensor chip, wherein a distance from the dummy pad to a central portion of the image sensor chip is smaller than a distance from the plurality of chip pads to the central portion;
a dam structure on the plurality of chip pads and the dummy pad; and
a transparent substrate on the image sensor chip and the dam structure,
wherein the image sensor chip comprises:
a plurality of micro lenses;
a planarization film on a lower side of the plurality of micro lenses; and
a passivation film covering the plurality of micro lenses,
wherein the planarization film is spaced apart from the dam structure,
wherein the passivation film covers a side surface of the planarization film and extends to a lower side of the dam structure,
wherein the plurality of chip pads and the plurality of substrate pads are connected to each other by bonding wires, and
wherein the dummy pad and the plurality of substrate pads are not connected to each other.
